(19) United States
(12) Patent Application Publication
(10) Pub. No.: US 2013/0220398 A1
(43) Pub. Date: Aug. 29, 2013

(54) SOLAR CELL AND METHOD FOR MANUFACTURING THE SAME

(71) Applicant: Chul Hwan Choi, Seoul (KR)

(72) Inventor: Chul Hwan Choi, Seoul (KR)

(73) Assignee: LG INNOTEK CO., LTD., Seoul (KR)

(21) Appl. No.: 13/882,639

(22) PCT Filed: Oct. 6, 2011
(86) PCT No.: PCT/KR2011/007401

§ 371 Date: Apr. 30, 2013

(30) Foreign Application Priority Data
Jan. 25, 2011 (KR) 10-2011-0007530

(51) Int. Cl. H01L 31/05

(52) U.S. Cl. CPC H01L 31/0508
USPC 136/244; 438/98

(57) ABSTRACT

Disclosed are a solar cell and a method for manufacturing the same. The solar cell includes a plurality of cells. Each cell includes a substrate, a back electrode layer on the substrate, a light absorbing layer on the back electrode layer, a buffer layer on the light absorbing layer, and a window layer on the buffer layer. When a width of each cell is W1, and a thickness of the window layer is W2, the width of each cell and the thickness of the window layer satisfy an equation of W2=A×W1, in which the A has a value in a range of about 1×10⁻⁴ to 1.7×10⁻⁴.

### TECHNICAL FIELD

The embodiment relates to a solar cell and a method for manufacturing the same.

### BACKGROUND ART

Recently, as energy consumption is increased, the development on a solar cell to convert solar energy into electrical energy has been performed.

In particular, a CIGS-based solar cell has been extensively used, in which the CIGS-based solar cell is a PN hetero junction device having a support substrate structure including a glass support substrate, a metallic back electrode layer, a P type CIGS-based light absorbing layer, a buffer layer, and an N type transparent electrode layer.

In addition, in order to increase the efficiency of the solar cell, various studies have been performed.

### DISCLOSURE OF INVENTION

### Technical Problem

The embodiment provides a solar cell and a method for manufacturing the same, capable of reducing the thickness of a window layer by adjusting the thickness of the window layer to a predetermined ratio according to the width of each cell, so that the productivity can be improved.

### Solution to Problem

According to the embodiment, a solar cell includes a plurality of cells. Each cell includes a substrate, a back electrode layer on the substrate, a light absorbing layer on the back electrode layer, a buffer layer on the light absorbing layer, and a window layer on the buffer layer. When a width of each cell is W1, and a thickness of the window layer is W2, the width of each cell and the thickness of the window layer satisfy an equation of W2=×, in which the A has a value in a range of about 1×10⁻⁴ to 1.7×10⁻⁴.

According to the embodiment, a method for manufacturing a solar cell includes forming a back electrode layer on a substrate, forming a light absorbing layer, a buffer layer, and a window layer on the back electrode layer, and forming a plurality of through holes to define a plurality of windows and cells by partially removing the light absorbing layer, the buffer layer, and the window layer. When a width of each cell is W1, and a thickness of the window layer is W2, the width of each cell and the thickness of the window layer satisfy an equation of W2=A×W1, in which the A has a value in a range of about 1×10⁻⁴ to 1.7×10⁻⁴.

### Advantageous Effects of Invention

As described above, the thickness of a window layer can be reduced by adjusting the thickness of the window layer to a predetermined ratio according to the width of each cell, so that the productivity can be improved.

In addition, transmittance can be improved by reducing the thickness of a window, so that the photoelectric conversion efficiency can be improved.

### BRIEF DESCRIPTION OF DRAWINGS

FIG. 1 is a plan view showing a solar cell apparatus according to the embodiment;

FIG. 2 is a sectional view taken along line A-A′of FIGS. 1; and

FIGS. 3 to 6 are sectional views showing a method for manufacturing a solar cell according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” over the other substrate, layer (or film), region, pad, or pattern, or one or more intervening layers may also be present. Such a position of the layer has been described with reference to the drawings. The thickness and size of each layer shown in the drawings may be exaggerated, omitted or schematically drawn for the purpose of convenience or clarity. In addition, the size of elements does not utterly reflect an actual size.

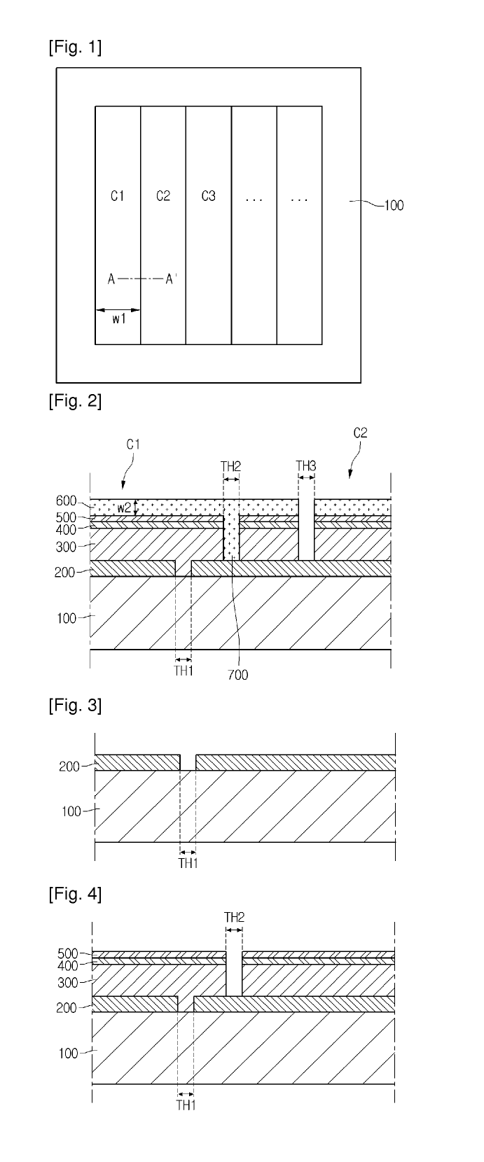

FIG. 1 is a plan view showing a solar cell apparatus according to the embodiment. FIG. 2 is a sectional view taken along line A-A′of FIG. 1.

Referring to FIG. 2, a solar cell according to the embodiment includes a support plate 100, a back electrode layer 200 on the support substrate 100, a light absorbing layer 300 on the back electrode layer 200, a buffer layer 400 and a high resistance buffer layer 500 on the a light absorbing layer 300, and a window layer 600 on the high resistance buffer layer 500.

The support substrate 100 has a plate shape and supports the back electrode layer 200, the light absorbing layer 300, the buffer layer 400, the high resistance buffer layer 500, and the window layer 600.

The support substrate 100 may include an insulator. The support substrate 100 may include a glass substrate, a plastic substrate, or a metallic substrate. In more detail, the support substrate 100 may include a soda lime glass substrate.

If the support substrate 100 includes soda lime glass, sodium (Na) contained in the soda lime glass may be diffused into the light absorbing layer 300 including CIGS when manufacturing the solar cell. Accordingly, the concentration of charges of the light absorbing layer 300 may be increased. Therefore, the photoelectric conversion efficiency can be increased.

In addition, the support substrate 100 may include a ceramic substrate including alumina, stainless steel, or polymer having flexibility. Therefore, the support substrate 100 may be transparent, rigid, or flexible.

The back electrode layer 200 is provided on the support substrate 100. The back electrode layer 200 is a conductive layer. The back electrode layer 200 moves charges generated from the light absorbing layer 300 of the solar cell so that current can flow to the outside of the solar cell. The back electrode layer 200 must represent high electrical conductivity or low resistivity to perform the functions.

The back electrode layer 200 must maintain stability under the high-temperature condition when the heat treatment process is performed under sulfur (S) or selenium (Se) atmosphere as a CIGS compound is formed. In addition, the back electrode layer 200 must represent a superior adhesive property with respect to the support substrate 100 such that the back electrode layer 200 is not delaminated from the support substrate 100 due to the difference in the thermal expansion coefficient between the back electrode layer 200 and the support substrate 100.

The back electrode layer 200 may include one selected from the group consisting of molybdenum (Mo), gold (Au), aluminum (Al), chrome (Cr), tungsten (W), and copper (Cu). Among them, the Mo represents the low thermal expansion coefficient difference with respect to the support substrate 100 as compared with other elements. Accordingly, the Mo represents a superior adhesive property with respect to the support substrate 100 to prevent the back electrode layer 200 from being delaminated the support substrate 100. In addition, the Mo satisfies the characteristics required for the back electrode layer 200.

The back electrode layer 200 may include at least two layers. In this case, the layers include the same metal, or different metals.

First through holes TH1 are formed in the back electrode layer 200. The first through holes TH1 are open regions to expose portions of the top surface of the support substrate 100. The first through holes TH1 may extend in one direction when viewed in a plan view.

The width of the support substrate 100 exposed through the first through hole TH1 may be in the range of about 80 μm to about 200 μm.

The back electrode layer 200 is divided into a plurality of back electrodes by the first through holes TH1. In other words, the back electrodes are defined by the first through holes TH1.

The back electrodes are arranged in the form of a stripe. In addition, the back electrodes may be arranged in the form of a matrix. In this case, the first through holes TH1 may be formed in the form of a lattice when viewed in a plan view.

The light absorbing layer 300 may be formed on the back electrode layer 200. The light absorbing layer 300 includes a P type semiconductor compound. In more detail, the light absorbing layer 300 includes group I-III-V compounds. For example, the light absorbing layer 300 may have a Cu—In—Ga—Se-based crystal structure (Cu(In,Ga)Se₂ ;CIGS), a Cu—In—Se-based crystal structure, or a Cu—Ga—Se based crystal structure.

The buffer layer 400 and the high resistance buffer layer 500 may be formed on the light absorbing layer 300. In a solar cell including a CIGS compound constituting the light absorbing layer 300, a PN junction is formed between a CIGS compound thin film including a P type semiconductor and the window layer 600 including an N type semiconductor. However, since two above materials represent great difference in a lattice constant and band gap energy, a buffer layer having the intermediate band gap between the band gaps of the two materials is required in order to form a superior junction.

The buffer layer 400 includes CdS or ZnS, and the CdS represents more improved generating efficiency of the solar cell.

The high-resistance buffer layer 500 includes i-ZnO that is not doped with impurities. The energy band gap of the high-resistance buffer layer 500 is in the range of about 3.1 eV to about 3.3 eV.

The window layer 600 is formed on the high-resistance buffer layer 500. The window layer 600 is a transparent conductive layer. In addition, the resistance of the window layer 600 is higher than the resistance of the back electrode layer 200.

The window layer 600 includes an oxide. For example, the window layer 600 may include zinc oxide, indium tin oxide (ITO), or indium zinc oxide (IZO).

In addition the oxide may include conductive impurities such as aluminum (Al), alumina (Al₂O₃), magnesium (Mg), or gallium (Ga). In more detail, the window layer 600 may include Al doped zinc oxide (AZO) or Ga doped zinc oxide (GZO).

According to the related art, a thickness W2 of the window layer 600 is formed at a constant ratio with respect to a width W1 of each cell C1, C2, . . . or Cn. For example, this is expressed by the following equation.

### Equation

W2=A×W1

In other words, if the width W1 of each cell C1, C2, . . . or Cn is 3 mm, the thickness

W2 of the window layer 600 becomes 600 nm. If the width W1 of each cell C1, C2, . . . or Cn is 4 mm, the thickness W2 of the window layer 600 becomes 800 nm. If the width W1 of each cell C1, C2, ... or Cn is 5 mm, the thickness W2 of the window layer 600 becomes 1000 nm.

According to the related art, since the thickness W2 of the window layer 600 is thicker than the width W1 of the each cell C1, C2, . . . or Cn as described above, the improvement is required in the cost and time of the production. In addition, the transmittance is degraded due to the thickness W2 of the thick window layer 600.

In addition, if the thickness W2 of the window layer 600 is increased, short may occur due to the particles of the window layer 600 when third through holes TH3 are formed.

In addition, if the width W1 of each cell C1, C2, . . . or Cn is reduced, an open voltage Voc may be increased. However, at the same time, a short current Isc is reduced, so that the efficiency of the solar cell may be reduced. If the width W1 of each cell C1, C2, . . . or Cn is excessively reduced, the open voltage Voc may be reduced. In this regard, the width W1 of each cell C1, C2, . . . or Cn may be preferably formed at a thickness in the range of about 3 mm to about 6 mm.

An equation to optimize the range of the width W1 of each cell C1, C2, . . . or Cn and the thickness W2 of the window layer 600 capable of improving productivity is expressed as follows.

### Equation

W2=A×W1

In the equation, if the value of A is reduced to 1×10⁻⁴ or less, the resistance characteristic of the window layer 600 may be degraded. If the value of A is increased to 1.5×10⁻⁴or more, the thickness W2 of the window layer 600 is increased, so that the transmittance is reduced and the cost of the production is increased.

The width W1 of each cell C1, C2, . . . or Cn refers to a distance between one third through hole TH3 and an adjacent third through hole TH3.

Accordingly, the A may have a value of 1×10⁻⁴ to 1.7×10⁻⁴ . Preferably, the A may have a value of 1.2×10⁻⁴ to 1.3×10⁻⁴.

In other words, if the width W1 of each cell C1, C2, . . . or Cn is 3 mm, the thickness W2 of the window layer 600 is 375 nm. If the width W1 of each cell C1, C2, . . . or Cn is 4 mm, the thickness W2 of the window layer 600 is 500 nm. If the width W1 of each cell C1, C2, . . . or Cn is 5 mm, the thickness W2 of the window layer 600 is 625 nm.

According to the embodiment, the thickness W2 of the window layer 600 is reduced by adjusting the thickness W2 of the window layer 600 to a predetermined ratio according to the width of the W1 of each cell, so that the productivity can be improved.

Transmittance can be improved by reducing the thickness of the window layer, so that the photoelectric conversion efficiency can be improved.

FIGS. 3 to 6 are sectional views showing the method for manufacturing the solar cell apparatus according to the embodiment. The method for manufacturing the solar cell apparatus will be described based on the description about the solar cell apparatus.

Referring to FIG. 3, after forming the back electrode layer 200 on the support substrate 100, the back electrode layer 200 is patterned, thereby forming the first through holes TH1. Accordingly, a plurality of the back electrodes are formed on the support substrate 100. The back electrode layer 200 is patterned by using a laser.

The first through holes TH1 expose the top surface of the support substrate 100, and may have a width in the range of about 80 μm to about 200 μm.

In addition, an additional layer such as an anti-diffusion layer may be interposed between the support substrate 100 and the back electrode layer 200. In this case, the first through holes TH1 expose the top surface of the additional layer.

For example, the first through holes TH1 may be formed by a laser beam having a wavelength in the range of about 200 nm to about 600 nm.

Referring to FIG. 4, the light absorbing layer 300, the buffer layer 400, and the high resistance buffer layer 500 are formed on the back electrode layer 200.

The light absorbing layer 300 may be formed through a sputtering process or an evaporation scheme.

For example, the light absorbing layer 300 may be formed through various schemes such as a scheme of forming a Cu(In,Ga)Se₂ (CIGS) based-light absorbing layer 300 by simultaneously or separately evaporating Cu, In, Ga, and Se and a scheme of performing a selenization process after a metallic precursor film has been formed.

Regarding the details of the selenization process after the formation of the metallic precursor layer, the metallic precursor layer is formed on the back contact electrode 200 through a sputtering process employing a Cu target, an In target, or a Ga target.

Thereafter, the metallic precursor layer is subject to the selenization process so that the Cu(In,Ga)Se₂ (CIGS) based-light absorbing layer 300 is formed.

Different from the above, the sputtering process employing the Cu target, the In target, and the Ga target and the selenization process may be simultaneously performed.

In addition, a CIS or a CIG light absorbing layer 300 may be formed through a sputtering process employing only Cu and In targets or only Cu and Ga targets and the selenization process.

Thereafter, the buffer layer 400 may be formed after depositing cadmium sulfide through a sputtering process or a CBD (chemical bath deposition) scheme.

Next, a portion of the light absorbing layer 300, the buffer layer 400, and the high-resistance buffer layer 500 is removed, thereby forming second through holes TH2.

The second through holes TH2 may be formed through a mechanical device such as a tip or a laser.

For example, the light absorbing layer 300 and the buffer layer 400 may be patterned by the tip having a width of about 40 μm to about 180 μm. In addition, the second through holes TH2 may be formed by the laser having the wavelength of about 200 nm to about 600 nm.

The second through holes TH2 may have a width in the range of about 100 μm to about 200 μm.

In addition, the second through holes TH2 expose portions of the top surface of the back electrode layer 200.

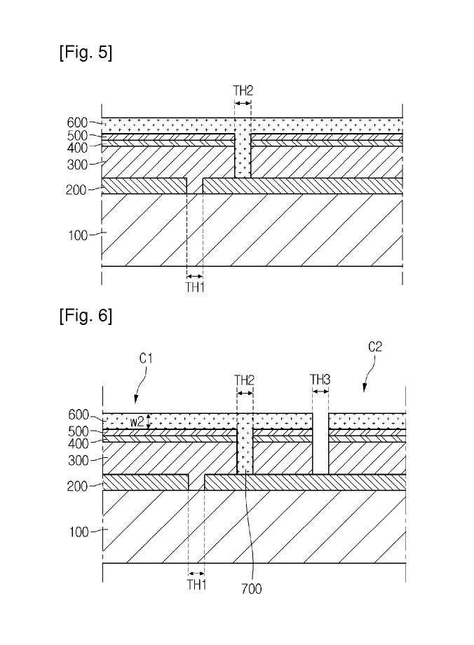

Referring to FIG. 5, the window layer 600 is formed above the light absorbing layer 300 and at inner parts of the second through holes TH2. In other words, the window layer 600 is formed by depositing a transparent conductive material above the buffer layer 400 and at the inner parts of the second through holes TH2.

In this case, the transparent conductive material is filled in the inner parts of the second through holes TH2, and the window layer 600 directly makes contact with the back electrode layer 200.

In this case, the window layer 600 may be formed by depositing a transparent conductive material at an oxygen-free atmosphere. In more detail, the window layer 600 may be formed by depositing AZO under the atmosphere of inert gas that does not include oxygen. In addition, the window layer 600 may be formed by deposing zinc oxide doped with Ga and Al.

Connection parts 700 are provided in the second through holes TH2. The connection parts 700 extend downward from the window layer 600 to make contact with the back electrode layer 200. For example, the connection part 700 extends from the window of the first cell to make contact with the back electrode of the second cell.

Accordingly, the connection parts 700 connect adjacent cells to each other. In more detail, the connection parts 700 connect the window layers 600 with the back electrodes included in adjacent cells C1, C2, . . . and Cn.

The connection part 700 is integrated with the window layer 600. In other words, the connection part 700 includes the same material as that constituting the window layer 600.

Referring to FIG. 6, the portions of the buffer layer 400, the high resistance buffer layer 500, and the window layer 600 are removed to form the third through holes TH3. Accordingly, the window layer 600 is patterned, thereby defining a plurality of windows and a plurality of cells C1, C2, . . . and Cn. The third through holes TH3 may have a width in the range of about 80 μm to about 200 μm.

As described above, a window layer having a reduced thickness can be formed, thereby improving productivity. In addition, transmittance can be improved, thereby proving a solar cell having improved.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure.

More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising a plurality of cells,
wherein each cell comprises:
a substrate;
a back electrode layer on the substrate;
a light absorbing layer on the back electrode layer;
a buffer layer on the light absorbing layer; and
a window layer on the buffer layer, and
wherein, when a width of each cell is W1, and a thickness of the window layer is W2, the width of each cell and the thickness of the window layer satisfy an equation of W2=A×W1, in which the A has a value in a range of about 1×10⁻⁴ to 1.7×10⁻⁴.

2. The solar cell of claim 1, wherein the thickness of the window layer is in a range of about 3 mm to about 6 mm.

3. The solar cell of claim 1, wherein the window layer includes at least one selected from the group consisting of zinc oxide, indium tin oxide (ITO), indium zinc oxide (IZO), Al doped zinc oxide (AZO), and Ga doped zinc oxide (GZO).

4. The solar cell of claim 1, further comprising a high resistance buffer layer formed between the buffer layer and the window layer.

5. The solar cell of claim 1, further comprising a plurality of through holes formed between the cells, wherein each through hole has a width in a range of about 80 μm to about 200 μm.

6. A method for manufacturing a solar cell, the method comprising:
forming a back electrode layer on a substrate;
forming a light absorbing layer, a buffer layer, and a window layer on the back electrode layer; and
forming a plurality of through holes to define a plurality of windows and cells by partially removing the light absorbing layer, the buffer layer, and the window layer,
wherein, when a width of each cell is W1, and a thickness of the window layer is W2, the width of each cell and the thickness of the window layer satisfy an equation of W2=A×W1, in which the A has a value in a range of about 1×10⁻⁴ to 1.7×10⁻⁴.

7. The method of claim 6, further comprising forming a high resistance buffer layer between the buffer layer and the window layer.
